(19) United States
(12) Patent Application Publication
(10) Pub. No.: US 2018/0142358 A1
(43) Pub. Date: May 24, 2018

(54) METHOD AND REAGENT FOR TREATING BARE COPPER WIRE AND SURFACE-TREATED COPPER WIRE

(71) Applicant: Samsung Electronics Co., Ltd., Suwon-si (KR)

(72) Inventor: Peng ZHANG, Suzhou (CN)

(73) Assignee: Samsung Electronics Co., Ltd., Suwon-si (KR)

(21) Appl. No.: 15/701,924

(22) Filed: Sep. 12, 2017

(30) Foreign Application Priority Data
Nov. 23, 2016 (CN) 201611047684.6

(51) Int. Cl. C23C 22/07; C23F 11/167

(52) U.S. Cl. CPC C23C 22/07; H01L 24/85; H01L 2224/85011; C23F 11/1676

(57) ABSTRACT

A method for treating a bare copper wire and a surface-treated copper wire includes applying a solution including a phosphoric acid-based chelating agent to a surface of a bare copper wire, and drying the copper wire having the solution including the phosphoric acid-based chelating agent attached on the surface thereof.

### CROSS-REFERENCE TO RELATED APPLICATION

This application claims priority to and the benefit of Chinese Patent Application No. 201611047684.6 filed in the Chinese Patent Office on Nov. 23, 2016, the entire contents of which are incorporated herein by reference.

### BACKGROUND

### 1. Field

Example embodiments relate to surface treatment of metal, more particularly, to a method and a reagent for treating a bare copper wire, and a surface-treated copper wire.

### 2. Description of the Related Art

In a semiconductor packaging process, wire bonding is an important step to be performed before molding a die. Generally, the wire bonding is performed by using a gold wire. However, the manufacturing cost of semiconductor devices becomes higher as the price of gold increases, thereby reducing competitive strength of products. Accordingly, a copper wire having a lower price and an improved conductivity in place of the gold wire has been developed.

A process of manufacturing a copper wire may include melting and casting, ingot casting, extension, stretching, heat treatment and winding. In the process of manufacturing the copper wire, a surface of the copper wire may be unavoidably oxidized, such that the engineering workability and reliability of a subsequent wire bonding process deteriorate. Therefore, reducing or preventing the surface of the copper wire from being oxidized and corroded may be necessary.

### SUMMARY

Example embodiments provide a method and a reagent for treating a bare copper wire and a surface-treated copper wire.

Example embodiments also provide a method and a reagent for treating a bare copper wire and a surface-treated copper wire capable of reducing or preventing a surface of the bare copper wire from being oxidized and corroded.

According to example embodiments, the method for treating a bare copper wire includes applying a solution including a phosphoric acid-based chelating agent to a surface of a bare copper wire, and drying the copper wire having the solution including the phosphoric acid-based chelating agent attached on the surface thereof.

Applying a solution may include spraying the solution including the phosphoric acid-based chelating agent on the bare copper wire, or dipping the bare copper wire into the solution including the phosphoric acid-based chelating agent.

Drying the copper wire may include blowing hot air on the bare copper wire having the solution including the phosphoric acid-based chelating agent attached on the surface thereof, drying the copper wire having the solution including the phosphoric acid-based chelating agent attached on the surface thereof in an oven, or naturally drying the copper wire having the solution including the phosphoric acid-based chelating agent attached on the surface thereof at an ambient temperature.

The solution including the phosphoric acid-based chelating agent may include 0.5 wt % to 2 wt % of the phosphoric acid-based chelating agent, 0.1 wt % to 1.5 wt % of a surfactant, and 96.7 wt % to 99.2 wt % of water.

The phosphoric acid-based chelating agent may include at least one of the following compounds:

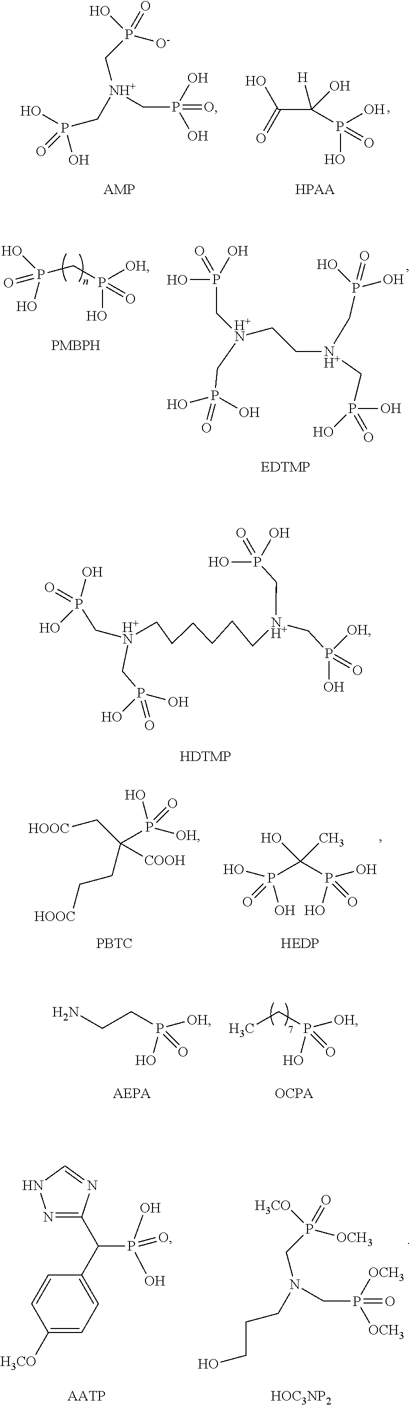

The surfactant may be a nonionic surfactant.

According to example embodiments, the reagent for treating a bare copper wire includes 0.5 wt % to 2 wt % of a phosphoric acid-based chelating agent, 0.1 wt % to 1.5 wt % of a surfactant, and 96.7 wt % to 99.2 wt % of water.

According to example embodiments, the surface-treated copper wire includes a copper wire base and a copper-organic compound film on a surface of the copper wire base.

The copper-organic compound film may have a thickness ranging from 1 nm to 10 nm.

The copper-organic compound film may have a fixed structural unit.

According to example embodiments, a method of manufacturing a semiconductor package includes the method of example embodiments.

According to example embodiments, a method includes applying a phosphoric acid-based compound to a surface of a copper wire coated with a copper-organic compound film.

Applying the phosphoric acid-based compound may spray a solution including the phosphoric acid-based compound on the copper wire.

Applying the phosphoric acid-based compound may dip the copper wire into a solution including the phosphoric acid-based compound.

The method may further include drying the copper wire having the phosphoric acid-based compound attached on the surface thereof.

Drying the copper wire may blow hot air on the copper wire having the phosphoric acid-based compound attached on the surface thereof.

Drying the copper wire may dry the copper wire having the phosphoric acid-based compound attached on the surface thereof in an oven.

Drying the copper wire may naturally dry the copper wire having the phosphoric acid-based compound attached on the surface thereof at an ambient temperature.

The phosphoric acid-based compound may be at least one of the following compounds:

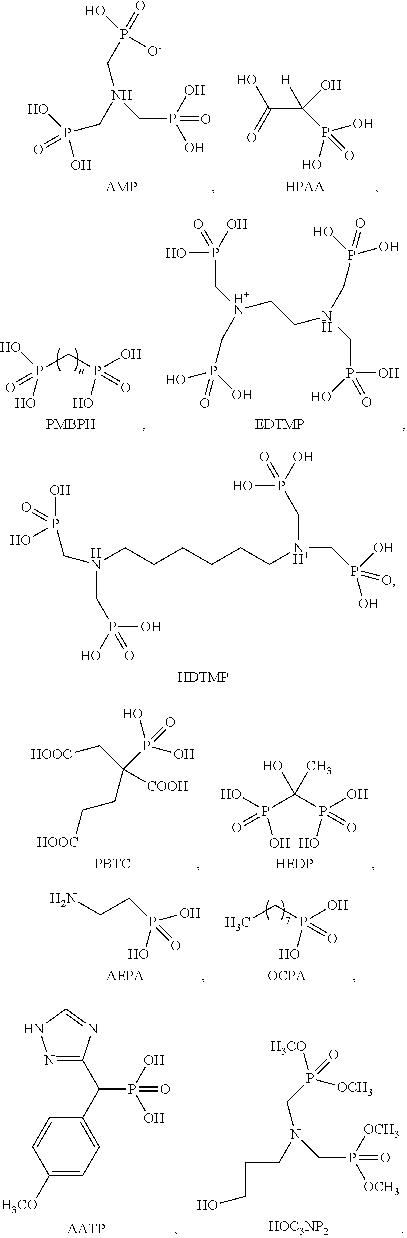

The phosphoric acid-based compound may be included in a chelating agent, and the chelating agent is included in a solution.

The solution may include 0.5 wt % to 2 wt % of the chelating agent, 0.1 wt % to 1.5 wt % of a surfactant, and 96.7 wt % to 99.2 wt % of water.

The surfactant may be a nonionic surfactant.

According to example embodiments, a method of manufacturing a semiconductor package includes the method of example embodiments.

### BRIEF DESCRIPTION OF THE DRAWINGS

These and/or other objects and aspects of the present disclosure will become more apparent from the following description of example embodiments, taken in conjunction with the accompanying drawing, in which:

FIG. 1 is a flowchart diagram illustrating a method for treating a bare copper wire according to example embodiments;

FIG. 2 is a schematic perspective view illustrating a surface-treated copper wire according to example embodiments;

FIG. 3 is a schematic cross-sectional view illustrating a surface-treated copper wire according to example embodiments;

FIG. 4 is a microphotograph illustrating a surface of a surface-treated copper wire after being treated by an acid according to example embodiments; and

FIG. 5 is a microphotograph illustrating a surface of a bare copper wire after being treated by an acid.

### DETAILED DESCRIPTION

Reference will now be made in detail to embodiments and methods of the present disclosure, which constitute the best modes of practicing the disclosure presently known to the inventors. The figures are not necessarily to scale, wherein like numerals refer to like elements throughout. However, it is to be understood that the disclosed embodiments are merely examples of the disclosure that may be embodied in various and alternative forms. Therefore, specific details disclosed herein are not to be interpreted as limiting, but merely as a representative basis for any aspect of the disclosure and/or as a representative basis for teaching one skilled in the art to variously employ the present disclosure.

Hereafter, a method for treating a bare copper wire according to example embodiments will be described in detail with reference to the accompanying drawings.

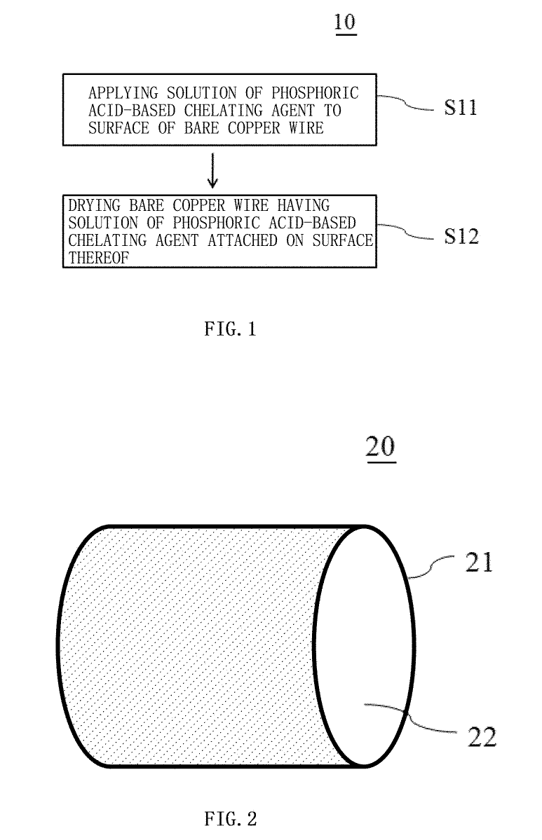

FIG. 1 is a flowchart diagram illustrating a method for treating a bare copper wire according to example embodiments. Referring to FIG. 1, a method 10 for treating a bare copper wire according to example embodiments includes applying a solution including a phosphoric acid-based chelating agent to a surface of a bare copper wire (step S11), and drying the copper wire having the solution including the phosphoric acid-based chelating agent attached on the surface thereof (step S12).

The bare copper wire may be a copper wire without an oxidized surface. In example embodiments, the bare copper wire is a bare copper wire that has just been heat treated and not been winded in a manufacturing process of the copper wire. The bare copper wire may have a diameter less than 0.5 mm, 0.2 mm, 0.1 mm, 0.08 mm, 0.06 mm, 0.04 mm, 0.02 mm, or 0.01 mm.

The solution including the phosphoric acid-based chelating agent includes a phosphoric acid-based chelating agent and a surfactant as a solute and water as a solvent.

The phosphoric acid-based chelating agent may include at least one of the following compounds:

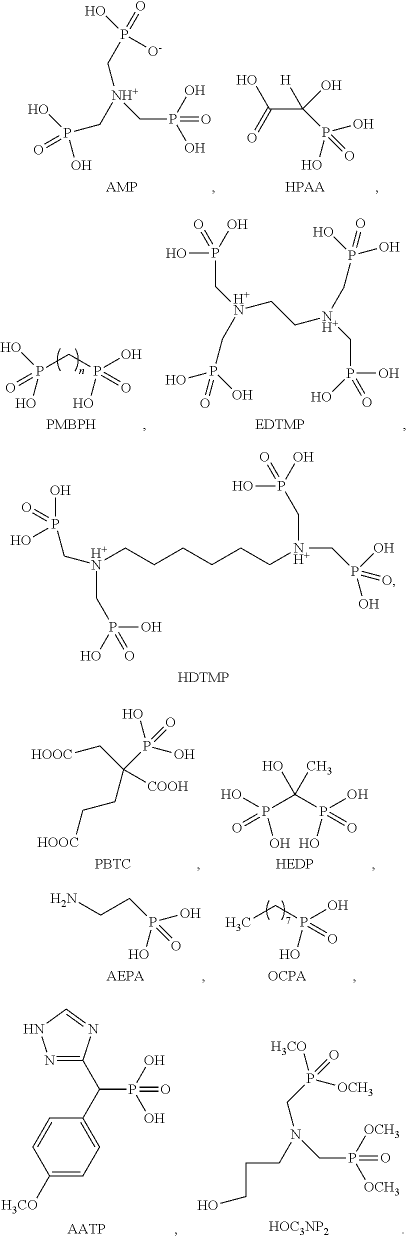

The surfactant may be a nonionic surfactant. The nonionic surfactant may include at least one of a polyethylene glycol-type nonionic surfactant, a polyol-type nonionic surfactant, and a nonionic fluorocarbon surfactant. The polyethylene glycol-type nonionic surfactant may include at least one of polyethylene glycol, alkylphenol ethoxylate, higher fatty alcohol polyoxyethylene ether, fatty acid polyoxyethylene ester, polyoxyethylene amine, polyoxyethylene amide, or an adduct of polypropylene glycol with ethylene oxide. The polyol-type nonionic surfactant may include at least one of sorbitan ester-type, sucrose ester-type, and alkyl alcohol amide-type nonionic surfactants. For example, the surfactant used in the solution including the phosphoric acid-based chelating agent is a nonionic surfactant, i.e., a polyethylene glycol-type nonionic surfactant. As an example, the polyethylene glycol-type nonionic surfactant is polyethylene glycol.

In example embodiments, the step S11 may be performed by spraying. For example, the solution including the phosphoric acid-based chelating agent is charged into a container equipped with a shower nozzle, and then is sprayed to a surface of the bare copper wire through the shower nozzle such that the surface of the bare copper wire contacts the solution including the phosphoric acid-based chelating agent. During spraying, the bare copper wire may be rotated at a constant rate in a circumferential direction such that the solution including the phosphoric acid-based chelating agent can contact the surface of the bare copper wire uniformly. The spraying may be performed for about 60 seconds to about 90 seconds.

In example embodiments, the step S11 may be performed by dipping the bare copper wire into the solution including the phosphoric acid-based chelating agent. The dipping may be performed for about 60 seconds to about 90 seconds.

In example embodiments, the step S12 may be performed by blowing hot air to the bare copper wire having the solution including the phosphoric acid-based chelating agent attached on the surface thereof. The hot air may have a temperature ranging from about 40° C. to about 80° C., and may be blown for about 1 minute to about 5 minutes.

In example embodiments, the step S12 may be performed by drying the copper wire having the solution including the phosphoric acid-based chelating agent attached on the surface thereof in the oven. The oven may include a space inside thereof having a temperature from about 40° C. to about 70° C., and the drying may be performed in the oven for about 5 minutes to about 20 minutes.

In example embodiments, the step S12 may be performed by naturally drying the copper wire having the solution including the phosphoric acid-based chelating agent attached on the surface thereof, at an ambient temperature, e.g., room temperature. The naturally drying process may be performed for about 10 minutes to about 120 minutes.

When the surface of the bare copper wire contacts the solution including the phosphoric acid-based chelating agent, the bare copper wire reacts with the phosphoric acid-based chelating agent to produce a copper-organic compound film which is chemically inert. The copper-organic compound film has improved oxidation resistance and corrosion resistance as compared with the surface of the bare copper wire. Therefore, such surface-treated copper wire has improved oxidation resistance and corrosion resistance as compared with the bare copper wire, thereby having improved engineering workability and reliability.

After the step S12 is completed, a copper-organic compound film having a thickness ranging from, for example, 1 nm to 10 nm (for example, 2 nm to 8 nm, or 3 nm to 7 nm), may be formed on the surface of the bare copper wire. If the copper-organic compound film is too thin, sufficient oxidation resistance and corrosion resistance may not be provided. If the thickness of the copper-organic compound film is more than 10 nm, a defect may be caused in the wire bonding.

The solution including the phosphoric acid-based chelating agent may include 0.5 wt % to 2 wt % of the phosphoric acid-based chelating agent, 0.1 wt % to 1.5 wt % of the surfactant, and 96.7 wt % to 99.2 wt % of water based on the total weight of the solution including the phosphoric acid-based chelating agent. In example embodiments, the solution including the phosphoric acid-based chelating agent may include 0.7 wt % to 1.5 wt % of the phosphoric acid-based chelating agent, 0.4 wt % to 1.2 wt % of the surfactant, and 97.5 wt % to 98.6 wt % of water. In example embodiments, the solution including the phosphoric acid-based chelating agent may include 0.8 wt % to 1.2 wt % of the phosphoric acid-based chelating agent, 0.5 wt % to 0.9 wt % of the surfactant, and 98.0 wt % to 98.5 wt % of water. In example embodiments, the solution including the phosphoric acid-based chelating agent may include 1 wt % of the phosphoric acid-based chelating agent, 0.5 wt % of the surfactant, and 98.5 wt % of water.

Forming the copper-organic compound film efficiently may be difficult if the content of the phosphoric acid-based chelating agent is less than 0.5 wt %. If the content of the phosphoric acid-based chelating agent is more than 2 wt %, the formed copper-organic compound film may be undesirably thick so that a defect may occur in the wire bonding.

The surfactant may promote the reaction between the bare copper wire and the phosphoric acid-based chelating agent. If the content of the surfactant is less than 0.1 wt %, the reaction between the bare copper wire and the phosphoric acid-based chelating agent may not be promoted. If the content of the surfactant is more than 1.5 wt %, the reaction between the bare copper wire and the phosphoric acid-based chelating agent may be unstable.

In example embodiments, the solution including the phosphoric acid-based chelating agent may include additional components, for example, a stabilizer which is beneficial to long-term storage of the solution including the phosphoric acid-based chelating agent. In example embodiments, the solution including the phosphoric acid-based chelating agent consists of the phosphoric acid-based chelating agent, the surfactant, and water having contents described above.

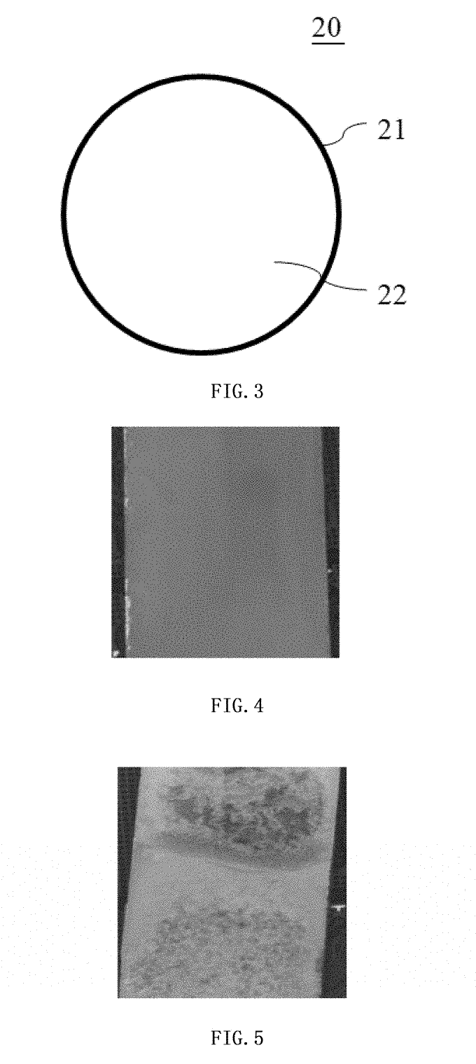

Hereinafter, a copper wire treated according to the above method will be described in detail with reference to FIGS. 2-5. FIG. 2 is a schematic perspective view illustrating a surface-treated copper wire according to example embodiments, and FIG. 3 is a schematic cross-sectional view illustrating the surface-treated copper wire according to example embodiments.

By referring to FIGS. 2-3, a surface-treated copper wire 20 includes a copper wire base 22 and a copper-organic compound film 21 coated on a surface of the copper wire base 22. The copper wire base 22 may have a diameter less than 0.5 mm, 0.2 mm, 0.1 mm, 0.08 mm, 0.06 mm, 0.04 mm, 0.02 mm, or 0.01 mm. The copper-organic compound film 21 may have a thickness ranging from, for example, 1 nm to 10 nm, 2 nm to 8 nm, or 3 nm to 7 nm.

During the contact of the surface of the bare copper wire with the solution including the phosphoric acid-based chelating agent, for example, in the step(s) S11 and/or S12, the bare copper wire reacts with the phosphoric acid-based chelating agent (for example, coordination between copper ions on the surface of the bare copper wire and the phosphoric acid-based chelating agent) to produce the copper-organic compound film 21 which is chemically inert. The copper-organic compound film 21 may have improved oxidation resistance and corrosion resistance as compared with the surface of the copper wire base 22. Thus, the surface-treated copper wire 20 has improved oxidation resistance and corrosion resistance as compared with the bare copper wire, thereby having improved engineering workability and reliability.

In example embodiments, the copper-organic compound film 21 has a fixed structural unit, which may be represented by the following Formula 1:

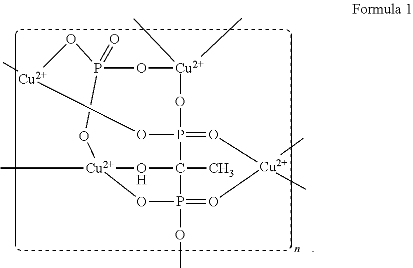

The copper-organic compound film 21 having the fixed structural unit represented by Formula 1 has improved oxidation resistance and corrosion resistance, and thus may protect the copper wire base 22 from being oxidized and corroded.

The above examples of the phosphoric acid-based chelating agent have a phosphate radical (—H₂PO₃) or a phosphate ester group (for example, a dimethyl phosphate group) as an effective functional group, which coordinates with the copper ions, and thus, the phosphoric acid-based chelating agent may more easily produce the fixed structural unit represented by, for example, above Formula 1, together with the copper ions.

A surface-treated copper wire according to example embodiments and a bare copper wire were treated by a hydrochloric acid solution having a pH of about 2.5. The microphotographs of the surface-treated copper wire and the bare copper wire which had been treated by the acid are illustrated in FIGS. 4-5, respectively.

Referring to FIG. 4, it was confirmed that the surface-treated copper wire 20 according to example embodiments had a smooth surface after being treated by the acid, without a blackening phenomenon. Referring to FIG. 5, it was confirmed that the bare copper wire after being treated by the acid in the same condition had a rough surface, with a portion of the surface being blackened, that is to say, an obvious oxidation and corrosion phenomenon occurred.

Because the outer surface of the bare copper wire contacted the acid directly, the surface of the copper was oxidized to be copper oxide which is black. The uniform copper-organic compound film 21 was attached to the surface of the surface-treated copper wire 20, the surface of the copper wire base 22 did not contact the acid directly, and the copper-organic compound film 21 had a chemical resistance to the acid and oxygen. Thus, the surface-treated copper wire 20 did not demonstrate an oxidation and corrosion phenomenon after being treated by the acid, thereby demonstrating improved oxidation resistance and corrosion resistance.

Therefore, the method for treating a bare copper wire according to example embodiments can improve the oxidation resistance and corrosion resistance of the copper wire such that the treated copper wire can be used in a semiconductor packaging process, for example, request of the engineering workability and reliability of the wire bonding process.

Further, the method for treating a bare copper wire according to example embodiments uses relatively simple processes and can be performed at a relatively low cost, thereby reducing the cost of, for example, a semiconductor packaging process.

Although a method and a reagent for treating a bare copper wire and a surface-treated copper wire according to example embodiments have been described above with reference to the drawings, example embodiments are not limited thereto. It will be understood by those skilled in the art that various changes in form and detail may be made therein without departing from the spirit and scope of the present disclosure.

1. A method for treating a bare copper wire, the method comprising:
applying a solution including a phosphoric acid-based chelating agent to a surface of a bare copper wire; and
drying the copper wire having the solution including the phosphoric acid-based chelating agent attached on the surface thereof.

2. The method of claim 1, wherein the applying comprises:
spraying the solution including the phosphoric acid-based chelating agent on the bare copper wire; or
dipping the bare copper wire into the solution including the phosphoric acid-based chelating agent.

3. The method of claim 1, wherein the drying comprises:
blowing hot air on the copper wire having the solution including the phosphoric acid-based chelating agent attached on the surface thereof.

4. The method of claim 1, wherein the solution including the phosphoric acid-based chelating agent includes 0.5 wt % to 2 wt % of the phosphoric acid-based chelating agent, 0.1 wt % to 1.5 wt % of a surfactant, and 96.7 wt % to 99.2 wt % of water.

5. The method of claim 4, wherein the phosphoric acid-based chelating agent includes at least one of the following compounds:

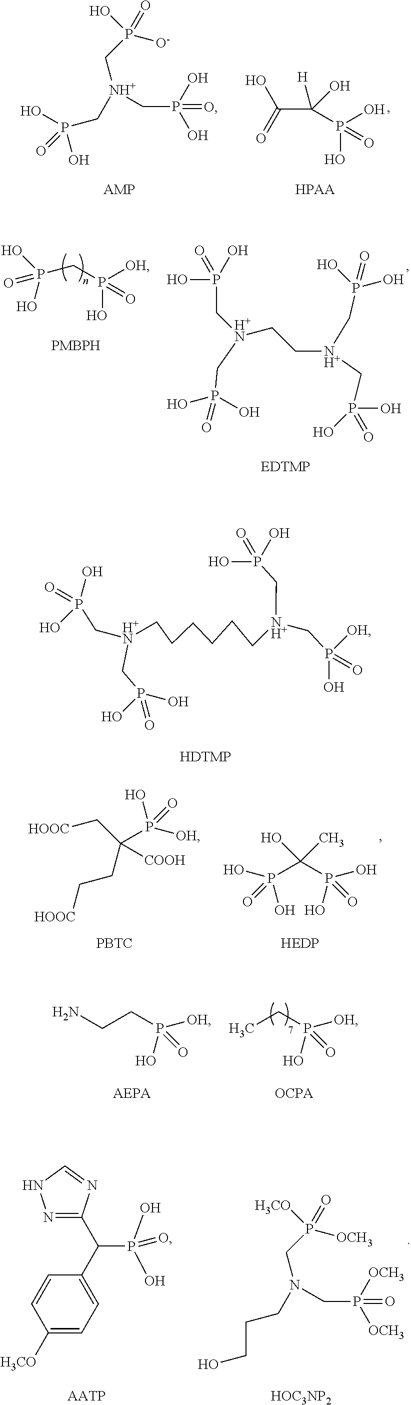

6. The method of claim 4, wherein the surfactant is a nonionic surfactant.

7-11. (canceled)

12. A method comprising applying a phosphoric acid-based compound to a surface of a copper wire coated with a copper-organic compound film.

13. The method of claim 12, wherein the applying sprays a solution including the phosphoric acid-based compound on the copper wire.

14. The method of claim 12, wherein the applying dips the copper wire into a solution including the phosphoric acid-based compound.

15. The method of claim 12, further comprising:
drying the copper wire having the phosphoric acid-based compound attached on the surface thereof.

16. The method of claim 15, wherein the drying blows hot air on the copper wire having the phosphoric acid-based compound attached on the surface thereof.

17. The method of claim 15, wherein the drying dries the copper wire having the phosphoric acid-based compound attached on the surface thereof in an oven.

18. The method of claim 15, wherein the drying naturally dries the copper wire having the phosphoric acid-based compound attached on the surface thereof at an ambient temperature.

19. The method of claim 12, wherein the phosphoric acid-based compound is at least one of the following compounds:

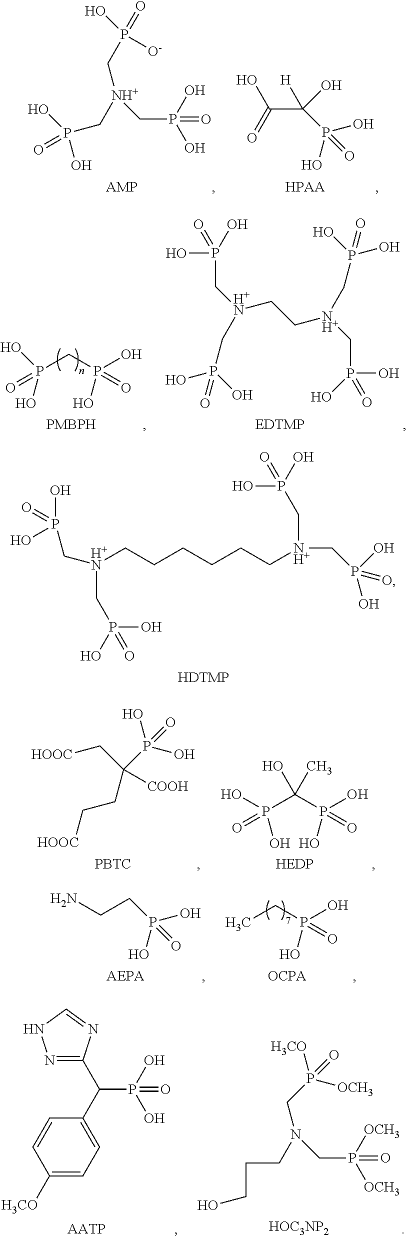

20. The method of claim 12, wherein
the phosphoric acid-based compound is included in a chelating agent; and
the chelating agent is included in a solution.

21. The method of claim 19, wherein the solution includes 0.5 wt % to 2 wt % of the chelating agent, 0.1 wt % to 1.5 wt % of a surfactant, and 96.7 wt % to 99.2 wt % of water.

22. The method of claim 19, wherein the surfactant is a nonionic surfactant.

23. A method of manufacturing a semiconductor package comprising the method of claim 12.
